(19) United States
(12) Patent Application Publication
(10) Pub. No.: US 2025/0077109 A1
(43) Pub. Date: Mar. 6, 2025

(54) ERASE VERIFICATION FOR A NONVOLATILE MEMORY

(71) Applicant: HEWLETT PACKARD ENTERPRISE DEVELOPMENT LP, Spring, TX (US)

(72) Inventors: Joseph Wright, Tomball, TX (US); Chris Davenport, Houston, TX (US); Luis E. Luciani, Jr., Tomball, TX (US)

(21) Appl. No.: 18/460,041

(22) Filed: Sep. 1, 2023

(51) Int. Cl. G06F 3/06

(52) U.S. Cl. CPC G06F 3/0652; G06F 3/0658; G06F 3/0679; G06F 3/0604

(57) ABSTRACT

In some examples, a system includes a nonvolatile memory to store information, and a controller subsystem to perform various tasks. The controller subsystem receives, from an entity, an input to trigger an erase verification operation after an erase of a memory region of the nonvolatile memory containing the information. The controller subsystem generates a pseudorandom pattern in response to the input, and writes the pseudorandom pattern to the memory region as part of the erase verification operation. After the writing, the controller subsystem provides, from the nonvolatile memory to the entity, the pseudorandom pattern retrieved from the memory region for verification that the erasing of the information of the memory region has occurred.

### BACKGROUND

An electronic device can include a memory to store information, including data, machine-readable instructions, configuration information, and so forth. The memory can include nonvolatile memory or volatile memory. Information stored in a volatile memory is lost if power is removed from the volatile memory. On the other hand, information stored in a nonvolatile memory is maintained by the nonvolatile memory even if power were to be removed from the nonvolatile memory.

### BRIEF DESCRIPTION OF THE DRAWINGS

Some implementations of the present disclosure are described with respect to the following figures.

FIG. 1 is a block diagram of a system that includes a controller that is able to generate a pseudorandom pattern to write to erased memory regions of a nonvolatile memory for the erase verification according to some examples.

FIG. 2A and FIG. 2B are flow diagrams of erase verification processes according to some examples.

FIG. 3 is a block diagram of a system according to some examples.

FIG. 4 is a block diagram of a storage medium storing machine-readable instructions according to some examples.

FIG. 5 is a flow diagram of a process according to some examples.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION

Information stored in a memory region of a nonvolatile memory in a computer system may be erased by using an erase operation that writes a specific erase pattern (e.g., all 0s or all 1s) to a memory region of the nonvolatile memory. If the computer system is compromised by an attacker, the attacker may prevent the erase operation from being completed to the memory region. The attacker may include malware executed in the computer system, or a physical component inserted in the computer system. By preventing the erase operation from being completed, the attacker can keep the information stored in the memory region, so that the information can later be retrieved and used in an unauthorized manner. The information in the memory region may include sensitive information that can be used to attack the system or other devices coupled to the system.

If an entity that requested the erase operation attempts to read the memory region to confirm that the erase operation was completed, the attacker may intercept the read request. Instead of returning the actual information in the memory region that was supposed to have been erased, the attacker may instead return the expected erase pattern to the entity. The entity receiving the erase pattern from the attacker is deceived into believing that the erase operation was completed when in fact the sensitive information is still stored in the memory region.

In accordance with some implementations of the present disclosure, after a memory region of a nonvolatile memory has been erased, a controller in a computer system can participate in a secure erase verification operation for verifying that the memory region was successfully erased. In some examples, a verifier (e.g., a human, a program, or a machine) sends an input (e.g., a request or any other type of input information) to the controller to initiate the erase verification operation. The controller generates a pseudorandom pattern in response to the input, and the controller writes the pseudorandom pattern to the memory region that was erased. The pseudorandom pattern is different from an erase pattern written to a nonvolatile memory by an erase operation. The verifier can issue a read request to retrieve the pseudorandom pattern from the memory region to confirm that the erase operation of the memory region was successfully completed.

If an attacker is present in the computer system and intercepts the read request from the verifier, the attacker would return an erase pattern, which is different from the pseudorandom pattern written to the memory region by the controller. If the verifier does not receive the pseudorandom pattern (and instead receives an erase pattern or another different pattern), then the verifier can make a determination that an anomaly has occurred, such as due to the presence of an attacker or a malfunction of the computer system. The verifier can provide an alert of the anomaly, or the verifier can initiate a remediation action to address the anomaly, such as by powering down or otherwise disabling the computer system or a portion of the computer system.

The verifier may be an electronic component or a program in the computer system. Alternatively, the verifier may be external of the computer system, and may include a user, a program, or a machine. A “computer system” can refer to a computer or an arrangement of multiple computers. A “computer” can refer to a desktop computer, a notebook computer, a tablet computer, a server computer, a vehicle, a household appliance, a storage system, a communication node, or any other type of electronic device.

A “pseudorandom pattern” that can be written to a memory region can refer to any pattern of information that is not a uniform pattern such as a pattern of all 0s or all 1s. Also, the pseudorandom pattern is unpredictable and incompressible. The pseudorandom pattern can include a random sequence of bits that is generated by a deterministic random bit generator (DRBG) based on an initial value referred to as a seed, for example. A DRBG can also be referred to as a pseudorandom number generator or a deterministic random number generator. More generally, a pseudorandom pattern can be generated by a pattern generator based on a seed. A variation in the value of the seed will cause the pattern generator to generate a different pseudorandom pattern.

A pattern is pseudorandom when the pattern is deterministic yet also effectively random as long as an internal operation of a process (e.g., the seed used and/or the algorithm used) that generated the pattern is hidden from observation. For cryptographic purposes, a pattern is effectively random if the pattern is computationally indistinguishable from random within a threshold of a target security strength. Examples of pseudorandom pattern generators include any or some combination of the following: a linear congruential generator, a Lehmer generator, a Park-Miller generator, or any other type of random number generator.

A pattern is unpredictable if an entity without access to the internal process of a generator of the pattern would not be able to reproduce the pattern. A pattern is incompressible if the compressibility of the information in the pattern is less than a specified threshold, e.g., the compressibility of the information in the pattern is less than 1%, 2%, 5%, or any other value. The “compressibility” of information refers to a relative amount of storage space reduction for storing the compressed information as compared to the storage space for storing the information prior to compression.

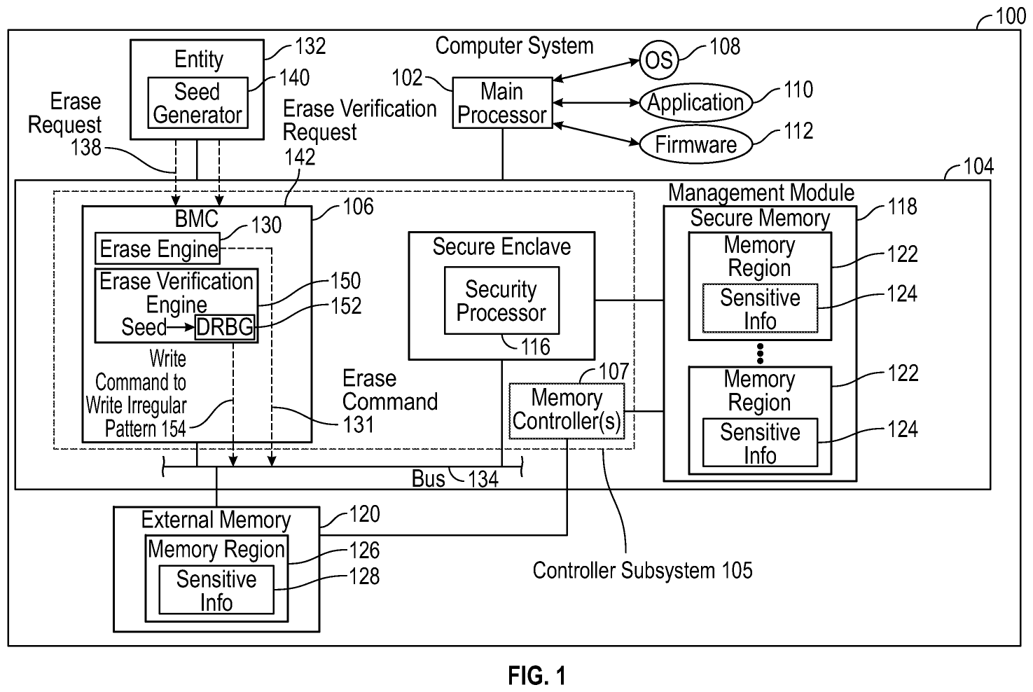

FIG. 1 is a block diagram of a computer system 100 that includes one or more main processors 102 and a management module 104. The management module 104 includes a baseboard management controller (BMC) 106, a secure enclave 114, and a secure memory 118. The management module 104 can be implemented with an integrated circuit chip, with a circuit board, or with an arrangement of discrete electronic components.

The BMC 106 performs various management tasks, which are discussed further below. Although reference is made to a BMC in some examples, other types of controllers can be used in other examples. As used here, a “controller” can refer to one or more hardware processing circuits, which can include any or some combination of a microprocessor, a core of a multi-core microprocessor, a microcontroller, a programmable integrated circuit, a programmable gate array, or another hardware processing circuit. Alternatively, a “controller” can refer to a combination of one or more hardware processing circuits and machine-readable instructions (software and/or firmware) executable on the one or more hardware processing circuits.

A processor can include a microprocessor, a core of a multi-core microprocessor, a microcontroller, a programmable integrated circuit, a programmable gate array, or another hardware processing circuit. The one or more main processors 102 of the computer system 100 can execute various machine-readable instructions of the computer system 100, such as an operating system (OS) 108, an application program 110, firmware 112 (e.g., including Basic Input Output System (BIOS) code or Unified Extensible Firmware Interface (UEFI) code), and other machine-readable instructions. The one or more main processors 102 may be coupled to the BMC 106, such as through an input/output (I/O) bridge (not shown), which is a device that interconnects various different components.

The secure enclave 114 (also referred to as a secure boundary or a secure perimeter) includes a subsystem of the management module 104 for which access into and out of the subsystem is more tightly controlled than access of other subsystems of the management module 104. For example, the secure enclave 114 is fully disposed inside a cryptographic boundary. A “cryptographic boundary” can refer to a continuous boundary, or perimeter, which contains the logical and physical components of a cryptographic subsystem, such as components of the secure enclave 114. The secure enclave 114, in accordance with some examples, is isolated from components outside the secure enclave 114. The cryptographic boundary is defined using a secure access mechanism such as by using encryption or another type of access control to protect components in the secure enclave 114 from unauthorized access by components outside the secure enclave 114.

The secure enclave 114 includes a security processor 116 that can perform various security-related functions of the management module 104, including generating and/or maintaining keys related to cryptographic operations, such as encryption keys to encrypt information/or private keys for signing information. The security processor 116 can also maintain security certificates used to authenticate an identity of an entity such as a user, a program, a website, an organization, a device, a program, or any other type of entity. Further examples of security-related functionalities that can be performed by the security processor 116 include root of trust operations (including measuring information such as machine-readable instructions, performing signature verification, performing decryption, performing attestation, etc.), random number and entropy generation, or other security-related functionalities.

As part of the security functionalities performed by the security processor 116, the security processor 116 can store sensitive information in the secure memory 118 of the management module 104. The secure memory 118 can be implemented using one or more nonvolatile memory devices, such as flash memory devices, erasable and programmable read-only memory (EPROM) devices, electrically erasable and programmable read-only memory (EEPROM) devices, and/or other types of nonvolatile memory devices. In some examples, the secure memory 118 is accessible by just components of the secure enclave 114, and the secure memory 118 is inaccessible to other components outside the secure enclave 114. Examples of sensitive information that can be stored in the secure memory 118 include keys (e.g., encryption keys, private keys, etc.), certificates, device identifiers, and so forth. If such sensitive information were to be accessed by an unauthorized entity (e.g., an attacker), the unauthorized entity can use the sensitive information to access other parts of the computer system 100 or to perform an operation in the computer system 100 that can cause errors or faults in the computer system 100.

The computer system 100 further includes an external memory 120, which is external of the management module 104. The external memory 120 can be implemented using one or more nonvolatile memory devices. In some examples, the external memory 120 can also store sensitive information, such as secret information, proprietary information of an enterprise, and so forth. Although not shown in FIG. 1, the computer system 100 can include other memories, including a memory accessible by the main processor(s) 102.

The BMC 106 and the security processor 116 of the secure enclave 114 are part of a controller subsystem 105 in the computer system 100. The controller subsystem 105 further includes one or more memory controllers 107 that can be used to access the secure memory 118 and/or the external memory 120. For example, the memory controller(s) 107 can be coupled to the secure memory 118 and/or the external memory 120 through a specific port, such as a Universal Serial Bus (USB) port or another port. As an example, the memory controller(s) 107 can be used for certain types of memory access, such as a memory read for verification of the content of a memory. The memory controller(s) 107 may not be used for other types of memory accesses, such as write operations.

More generally, a “controller subsystem” refers to a subsystem (i.e., a portion of a computer system) that includes one or more controllers.

As depicted in FIG. 1, the secure memory 118 includes one or more memory regions 122 that store respective sensitive information 124. Similarly, the external memory 120 includes one or more memory regions 126 that store respective sensitive information 128. A “memory region” of a memory can refer to a portion of the memory, where the portion can be made up of a contiguous section of the memory or made up of non-contiguous sections of the memory.

The BMC 106 is coupled over a bus 134 to the secure enclave 114 and to the external memory 120. The bus 134 can refer to any type of communication link over which electronic components are able to communicate.

In some examples, the BMC 106 includes an erase engine 130 that is able to erase information stored in any memory region of the secure memory 118 or the external memory 120. An “engine” of the BMC 106 includes a portion of the hardware processing circuitry of the BMC 106, or machine-readable instructions executable by the BMC 106.

The erase engine 130 can issue an erase command 131, which is sent over the bus 134. The erase command 131 is issued by the erase engine 130 in response to an erase request 138 sent from an entity 132 to the BMC 106. The entity 132 can include machine-readable instructions executed on the main processor(s) 102, or alternatively, the entity 132 can include a hardware component in the computer system 100. In further examples, the entity 132 can be external of the computer system 100. For example, such a remote entity can include a remote management controller that communicates with the BMC 106 over a management network.

The entity 132 can issue the erase request 138 for any of various different purposes. For example, the erase request 138 for the purpose of decommissioning the computer system 100. As another example, the erase request 138 may be issued when the computer system 100 is to be shipped to a repair facility to fix a problem in the computer system 100. The erase request can also be issued for any of various other reasons.

The erase command 131 from the erase engine 130 of the BMC 106 can be targeted to the secure memory 118 or the external memory 120. If the erase command 131 targets the secure memory 118, the security processor 116 receives the erase command 131 over the bus 134, and issues an erase operation to erase a memory region of the secure memory 118 specified by the erase command 131. If the erase command 131 targets the external memory 120, the external memory 120 receives the erase command 131 over the bus 134, and erases a memory region of the external memory 120 specified by the erase command 131.

The erase command from the erase engine 130 causes an erase pattern to be written to the specified memory region of the secure memory 118 or the external memory 120. The erase pattern can include a pattern of all 0s or all 1s, or any other predefined pattern that overwrites information stored in the memory region.

In accordance with some implementations of the present disclosure, the BMC 106 includes an erase verification engine 150 that is able to perform an erase verification operation to allow the entity 132 (or any other entity) to verify that a memory region of a memory (118 or 120) erased by the erase engine 130 was in fact successfully erased. In examples according to FIG. 1, the entity 132 can include a seed generator 140 that performs a key-agreement process with the erase verification engine 150 of the BMC 106 to generate a seed to be used as part of erase verification operation.

The seed generator 140 can be implemented using a portion of the hardware processing circuitry or machine-readable instructions of the entity 132. In some examples, the seed can include a random number (also referred to as a nonce).

The key-agreement process implements a key-agreement algorithm between two entities (the entity 132 and the erase verification engine 150 in FIG. 1) to establish a shared secret (the seed noted above) to be used for performing the erase verification operation. An example of a key-agreement algorithm is the Diffie-Hellman key-agreement algorithm. The key-agreement algorithm allows two or more entities to agree on the shared secret in such a way that the entities influence the outcome (the generated shared secret), while an unauthorized third party would not be able to force the choice of the shared secret. In examples according to some implementations of the present disclosure, the seed generated at each of the entity 132 and the BMC 106 is not shared between the entity 132 and the BMC 106, but rather are generated at each side based on an exchange according to the key-agreement algorithm.

The entity 132 can send an erase verification request 142 to the erase verification engine 150 to trigger the erase verification engine 150 to perform an erase verification operation. The erase verification request 142 can refer to a signal, a message, an information element, or any other type of input that indicates that an erase verification operation is to be initiated. The erase verification request 142 can identify a memory region for which an erase operation is to be verified (i.e., to confirm that the erase operation of the memory region was completed successfully). The erase verification request 142 can identify the memory region using a memory region identifier, such as a memory address of the memory region. Note that the erase verification request 142 can identify multiple memory regions to be verified.

In response to the erase verification request 142, a DRBG 152 in the erase verification engine 150 generates, based on the seed established using the key-agreement process, a pseudorandom pattern that is to be written to the identified memory region (e.g., the memory region that was subject to an erase operation). In some examples, the pseudorandom pattern generated by the DRBG 152 includes a random sequence of bits based on the seed. The seed is an input to the DRBG 152, which derives the random sequence of bits based on the seed. Different values of the see would cause the DRBG to generate different random sequences of bits.

The erase verification engine 150 issues a write command 154 to write the pseudorandom pattern generated by the DRBG 152 to the identified memory region. The write command 154 can be sent to the security processor 116 over the bus 134 to write the pseudorandom pattern to the identified memory region in the secure memory 118, or can be sent over the bus 134 to the external memory 120 to write the pseudorandom pattern to the identified memory region in the external memory 120.

At a later time, the entity 132 (or a different entity) can issue a read request to the controller subsystem 105 to retrieve the content of the identified memory region from the secure memory 118 or the external memory 120. The entity 132 can determine whether the information retrieved from the identified memory region matches the expected pseudorandom pattern. For example, the entity 132 can compare the pseudorandom pattern retrieved from the identified memory region to a stored pattern to determine a match. The stored pattern may be produced by a DRBG (not shown) in the entity 132 based on the seed generated by the entity 132 in the key-agreement process. The stored pattern may be stored in a memory accessible by the entity 132.

If the pseudorandom pattern retrieved from the identified memory region matches the stored pattern, the entity 132 makes a determination that the identified memory region was successfully erased. However, if the pseudorandom pattern retrieved from the identified memory region does not match the stored pattern, the entity 132 makes a determination that the identified memory region was not successfully erased. In the latter case (no match), the entity 132 can issue an alert (such as to an administrator) or can trigger a remediation action in the computer system 100.

In some examples, the read request from the entity 132 can be directed to the BMC 106 in the controller subsystem 105. In alternative examples, the read request from the entity 132 can be directed to another controller in the controller subsystem 105, where the other controller can be the security processor 116 or the memory controller(s) 107. The entity 132 can direct the read request to the BMC 106 by issuing a command to the BMC 106 through a port of the BMC 106. The entity 132 can direct the read request to the other controller by issuing a command to another port of the management module 104, such as a port connected to the security processor 116 or the memory controller(s) 107. A “port” can refer to any type of interface to communicate with a target component.

In some examples, the read request from the entity 132 can specify an arbitrary subregion of a memory region 122 or 126 to read. In further examples, multiple read requests from the entity 132 can specify multiple arbitrary subregions of a memory region 122 or 126 to read. A “subregion” of a memory region refers to a portion (less than the entirety) of the memory region. An “arbitrary” subregion can refer to a subregion selected arbitrarily by the entity 132 to read. For example, the subregion selected may be randomly selected from among multiple subregions of the memory region, or selected without any predefined rule. The ability to read arbitrary subregions of a memory region to perform secure erase verification reduces the likelihood that an unauthorized entity (e.g., an attacker) between the entity 132 and the memory can generate the pseudorandom pattern in a timely fashion to deceive the entity 132 into believing that the memory region was erased when in fact the memory region was not erased. For example, even if the attacker were to somehow determine the type of the DRBG 152 used and the seed used as an input to the DRBG 152, reading arbitrary subregions of the memory region out of order would mean that the attacker would have to regenerate the entire random sequence of bits to satisfy each read request. If the memory region is large (e.g., 1 gigabit or another large size), then the attacker would take a relatively long period of time to generate the entire random sequence of bits to satisfy each read request. A delay in obtaining a response to a read request (e.g., a delay that is greater than a maximum expected time for the controller subsystem 105 to read a memory) would be an indication to the entity 132 that an attacker is present or some other anomaly is present.

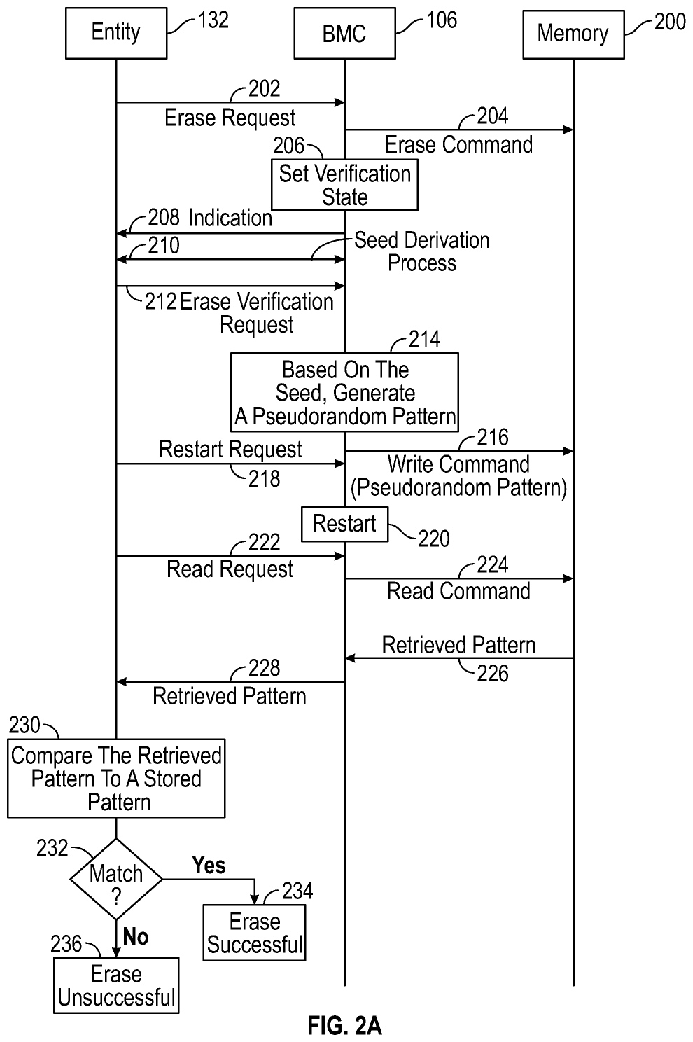

FIG. 2A is a flow diagram of a process that involves the entity 132, the BMC 106, and a memory 200 (which can be the secure memory 118 or the external memory 120, for example). Although FIG. 2A shows a specific order of tasks, in other examples, a process can employ a different order of the tasks, can include additional tasks, and/or can replace some of the tasks with different tasks.

The entity 132 sends (at 202) an erase request to the BMC 106. The erase request identifies a memory region to be erased. Note that identifying a memory region can refer to identifying one or more memory regions.

In response to the erase request, the erase engine 130 of the BMC 106 (FIG. 1) issues (at 204) an erase command to the memory 200 to perform an erase operation. The erase command causes an erase pattern to be written to the memory region identified by the erase command.

In some examples, in response to performing the erase operation, the BMC 106 can be set (at 206) itself to a specified verification state that indicates that an entity outside the BMC 106 is enabled to access the memory region that was erased, such as for verification of the erase operation. If the BMC 106 was not in the specified verification state, the BMC 106 may deny any request to access the memory region that was erased. In some examples of the present disclosure, the allowed access of the memory region is to allow a special pattern (the pseudorandom pattern discussed further above) to the written to the memory region that was erased.

The BMC 106 sends (at 208), to the entity 132, an indication (e.g., a message, an information element of a message, etc.) that remote verification of the erase is enabled. In response to the indication that the remote verification of the erase is enabled, the entity 132 performs (at 210) a seed derivation process with the BMC 106 (or more specifically, with the erase verification engine 150 of the BMC 106) to derive a seed to be used in the erase verification operation. For example, the seed derivation process can use a key-agreement algorithm as noted above. As a result of the seed derivation process, the seed is generated at each of the entity 132 and the BMC 106.

The entity 132 sends (at 212) an erase verification request to the BMC 106. The erase verification request identifies the memory region that is to be verified. In response to the seed and the BMC 106 being in the specified verification state, the DRBG 152 in the BMC 106 (FIG. 1) generates (at 214) a pseudorandom pattern. The BMC 106 issues (at 216) a write command to write the pseudorandom pattern to the memory region (in the memory 200) identified by the erase verification request.

In some examples, after the BMC 106 has written the pseudorandom pattern to the memory region, the BMC 106 can grant read-only access of the memory region to the entity 132. The read-only access prevents the memory region from being modified. FIG. 2A shows examples where the BMC 106 is involved in reading the pseudorandom pattern from the memory 200 as part of the erase verification operation. FIG. 2B shows alternative examples where the BMC 106 is not part of the read path to retrieve the pseudorandom pattern from the memory 200 as part of the erase verification operation; instead, a different controller is involved in retrieve the pseudorandom pattern from the memory 200 as part of the erase verification operation.

Prior to requesting the pseudorandom pattern from the memory 200, the entity 132 sends (at 218) a restart request to cause a restart of the BMC 106. As an example, the BMC 106 may include a reset input that when activated causes the restart of the BMC 106. As another example, the restart request may be a signal issued to circuitry that controls power to the BMC 106; this signal if activated causes removal of power from the BMC 106 and subsequent re-application of power to the BMC 106. The BMC 106 is restarted (at 220) in response to the restart request. Restarting the BMC 106 can cause power cycling of the BMC 106, in which power is removed from the BMC 106 and then re-applied to the BMC 106. Removing power from the BMC 106 causes any information stored in a volatile memory of the BMC 106 to be lost. In some examples, the seed generated by the BMC 106 in the key-agreement algorithm with the entity 132 may be stored in the volatile memory of the BMC 106. If power is removed from the BMC 106, then the seed is lost. By restarting the BMC 106, it can be ensured that any malware executing on the BMC 106 would not have access to the seed for use in re-generating the pseudorandom pattern.

The entity 132 sends (at 222) a read request to the BMC 106 to read the memory region (or an arbitrary subregion of the memory region). In response to the read request, the BMC 106 issues (at 224) a read command to the memory 200 to retrieve the content of the memory region (or the arbitrary subregion). In further examples, the entity 132 may send multiple read requests to the BMC 106 to read multiple arbitrary subregions of the memory region (to retrieve the pseudorandom pattern in the multiple arbitrary subregions).

The BMC 106 receives (at 226) the retrieved pseudorandom pattern from the memory region, and returns (at 228) the retrieved pseudorandom pattern to the entity 132. The entity 132 compares (at 230) the retrieved pseudorandom pattern to a stored pattern. The entity determines (at 232) if the compared patterns match. If the compared patterns match, the entity 132 makes a determination (at 234) that the memory region was successfully erased.

If the compared patterns do not match, then the entity 132 makes a determination (at 236) that the memory region was not successfully erased. In the latter case, the entity 132 can take action to address the anomaly, such as by issuing an alert or triggering a remediation action to address the anomaly.

FIG. 2B is a flow diagram of a process that involves the entity 132, the BMC 106, a read controller 250, and the memory 200 (which can be the secure memory 118 or the external memory 120, for example). Although FIG. 2B shows a specific order of tasks, in other examples, a process can employ a different order of the tasks, can include additional tasks, and/or can replace some of the tasks with different tasks.

In examples according to FIG. 2B, the read controller 250 (which is separate from the BMC 106) is used to retrieve the pseudorandom pattern from the memory 200 for an erase verification operation. In FIG. 2B, the BMC 106 is not involved in reading the pseudorandom pattern from the memory 200 for the erase verification operation. The read controller 250 can be the security processor 116 or the memory controller 107 of FIG. 1, for example.

Tasks assigned the same reference numerals as those in FIG. 2A are similar to the corresponding tasks of FIG. 2A. For example, tasks 202 to 216 of FIG. 2B are similar to the corresponding tasks 202 to 216 of FIG. 2A.

After the BMC 106 has written (at 216) the pseudorandom pattern to the memory 200, the entity 132 sends (at 252) a read request to the read controller 250 to read the memory region (or an arbitrary subregion of the memory region). In response to the read request, the read controller 250 issues (at 254) a read command to the memory 200 to retrieve the content of the memory region (or the arbitrary subregion). In further examples, the entity 132 may send multiple read requests to the read controller 250 to read multiple arbitrary subregions of the memory region (to retrieve the pseudorandom pattern in the multiple arbitrary subregions).

The read controller 250 receives (at 256) the retrieved pseudorandom pattern from the memory region, and returns (at 258) the retrieved pseudorandom pattern to the entity 132. Tasks 230 to 236 in FIG. 2B are similar to corresponding tasks in FIG. 2A for determining by the entity 132 whether or not the erase was successful.

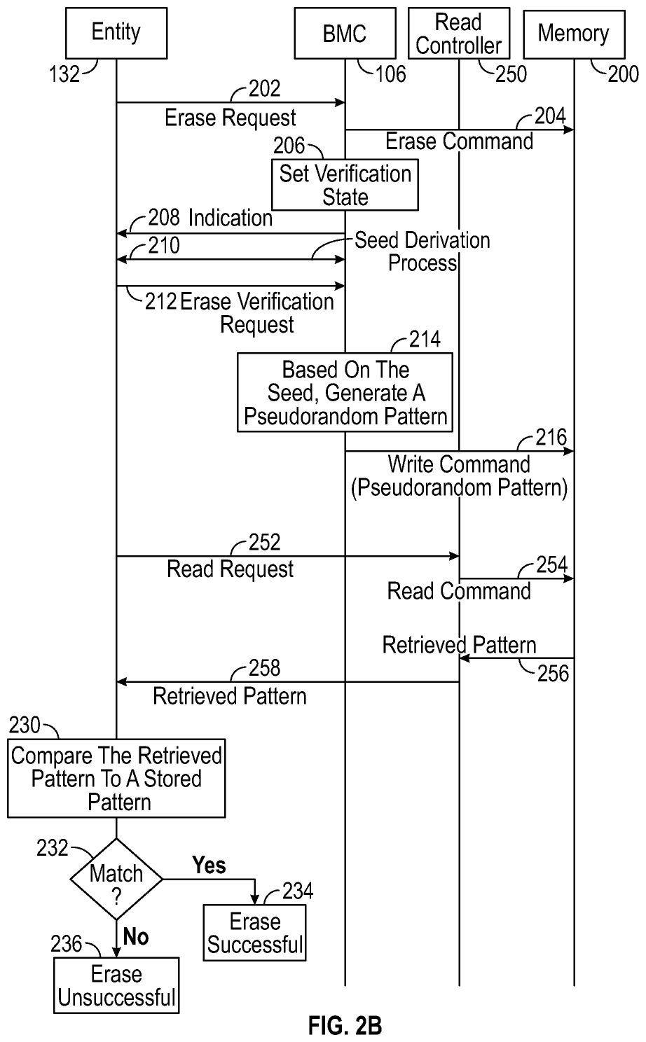

FIG. 3 is a block diagram of a system 300 according to some examples. The system 300 may be the computer system 100 or another system. The system 300 includes a nonvolatile memory 302 to store information 304. The nonvolatile memory 302 may be the secure memory 118 or the external memory 120 of FIG. 1, for example.

The system 300 includes a controller subsystem 306, such as the controller subsystem 105 of FIG. 1. The controller subsystem 306 includes one or more controllers that perform various tasks.

The tasks of the controller subsystem 306 include an erase verification input reception task 308 to receive, from an entity, an input (e.g., the erase verification request 142 of FIG. 1) to trigger an erase verification operation after an erase of a memory region of the nonvolatile memory containing the information. The entity may be the entity 132 of FIG. 1. The entity may be part of the system 300 or external of the system 300.

The tasks of the controller subsystem 306 include a pseudorandom pattern generation task 310 to generate a pseudorandom pattern in response to the input. The pseudorandom pattern may include a random pattern of bits, such as generated by the DRBG 152 of FIG. 1 based on a seed derived by a controller (e.g., a BMC) in the controller subsystem 306 using a key-agreement algorithm. In some examples, the pseudorandom pattern written to the memory region as part of the erase verification operation is different from an erase pattern written to the memory region to erase the information in the memory region

The tasks of the controller subsystem 306 include a pseudorandom pattern write task 312 to write the pseudorandom pattern to the memory region as part of the erase verification operation. The controller subsystem 306 performs the write by issuing a write command to the nonvolatile memory 302. For example, the write command to write the pseudorandom pattern may be performed by a BMC in the controller subsystem 306.

The tasks of the controller subsystem 306 include a pseudorandom pattern provision task 314 to, after the writing, provide, from the nonvolatile memory 302 to the entity, the pseudorandom pattern retrieved from the memory region for verification that the erasing of the information of the memory region has occurred. The entity can compare the retrieved pseudorandom pattern to a stored pattern to perform the verification. In some examples, the pseudorandom pattern can be retrieved from the memory region by the BMC of the controller subsystem 306 after a restart of the BMC (e.g., according to FIG. 2A). In other examples, the pseudorandom pattern can be retrieved from the memory region by a read controller (separate from the BMC) of the controller subsystem 306 (e.g., according to FIG. 2B).

In some examples, the controller subsystem 306 includes a first controller (e.g., a BMC) to receive the input to trigger the erase verification, generate the pseudorandom pattern, and write the pseudorandom pattern to the memory region. The controller subsystem 306 includes a second controller to read the pseudorandom pattern from the nonvolatile memory and provide the pseudorandom pattern read from the memory region to the entity, where the second controller is different from the first controller.

In further examples, the controller subsystem 306 includes a controller (e.g., the BMC 106 of FIG. 1) to receive the input to trigger the erase verification, generate the pseudorandom pattern, and write the pseudorandom pattern to the memory region. The controller further receives a trigger to restart the controller that causes a removal of power from the controller. After the restart of the controller, a read request is received from the entity to retrieve the pseudorandom pattern from the memory region. The controller provides, from the controller to the entity, the pseudorandom pattern retrieved from the memory region for the verification after the restart of the controller.

In some examples, the controller subsystem 306 receives a read request to read the pseudorandom pattern from the nonvolatile memory, where the pseudorandom pattern is retrieved from the memory region based on the read request. In some examples, the read request is for one or more arbitrary subregions of the memory regions, where the pseudorandom pattern provided to the entity is retrieved from the one or more arbitrary subregions.

In some examples, the controller subsystem 306 generates a seed based on a key-generation process with the entity. The pseudorandom pattern is a deterministic random sequence of bits generated based on the seed.

In some examples, after the erase of the memory region of the nonvolatile memory 302 containing the information 304, the controller subsystem 306 enables remote verification of the erase, and sends, to the entity, an indication that remote verification of the erase is enabled. The input to trigger the erase verification operation is provided by the entity to the controller subsystem 306 in response to the indication received by the entity from the controller subsystem 306.

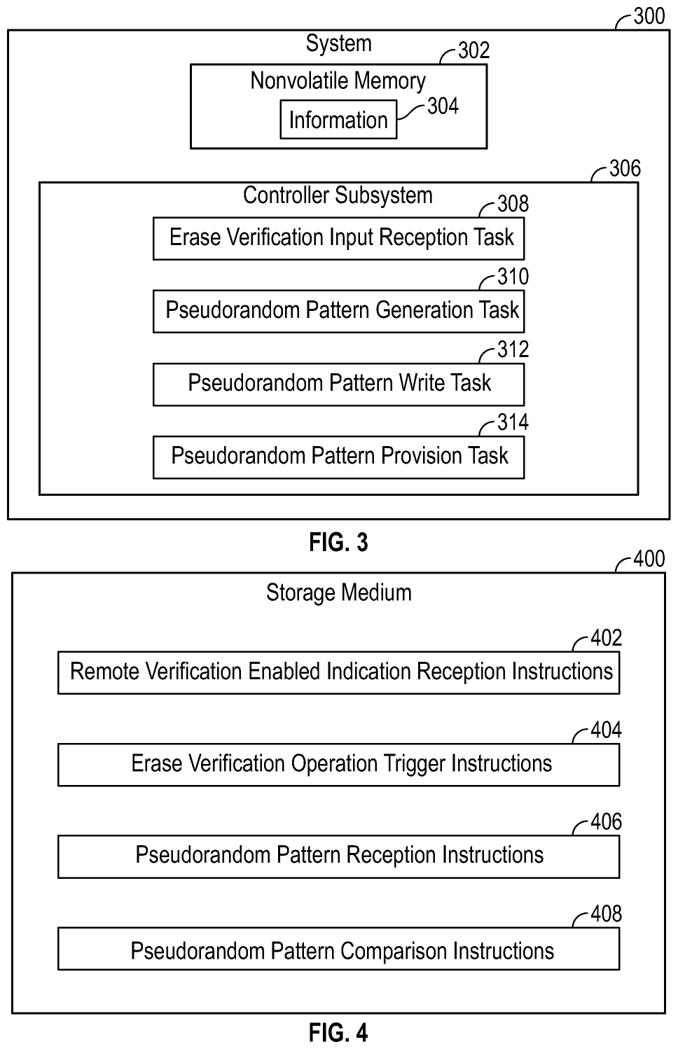

FIG. 4 is a block diagram of a non-transitory machine-readable or computer-readable storage medium 400 storing machine-readable instructions that upon execution cause a computer to perform various tasks. The computer may be an example of the entity 132 of FIG. 1 or another entity.

The machine-readable instructions include remote verification enabled indication reception instructions 402 to receive, from a controller in a system, an indication that remote verification of an erase of a memory region in a nonvolatile memory of the system is enabled. The controller may be the BMC 106 of FIG. 1, for example. The computer that executes the machine-readable instructions may be part of the system or separate from the system. The system in which the controller is provided may be the computer system 100 of FIG. 1, for example.

The machine-readable instructions include erase verification operation trigger instructions 404 to send, from the computer to the system after the receipt of the indication, an input to trigger an erase verification operation to verify the erase of the memory region. The input can be an erase verification request (e.g., 142 in FIG. 1 or 208 in FIG. 2).

The machine-readable instructions include pseudorandom pattern reception instructions 406 to receive, at the computer from the system, a pseudorandom pattern written by the controller to the memory region as part of the erase verification operation, where the pseudorandom pattern is generated based on a seed. For example, the pseudorandom pattern may be generated by a DRBG. The pseudorandom pattern may be retrieved from the memory region by the controller (after a restart of the controller) or by another controller that is without the seed.

The machine-readable instructions include pseudorandom pattern comparison instructions 408 to compare the received pseudorandom pattern with a stored pattern to verify that the erase of the memory region has occurred. If the compared patterns match, then that indicates the memory region was erased successfully. If the compared patterns do not match, then that indicates the memory region was not erased successfully.

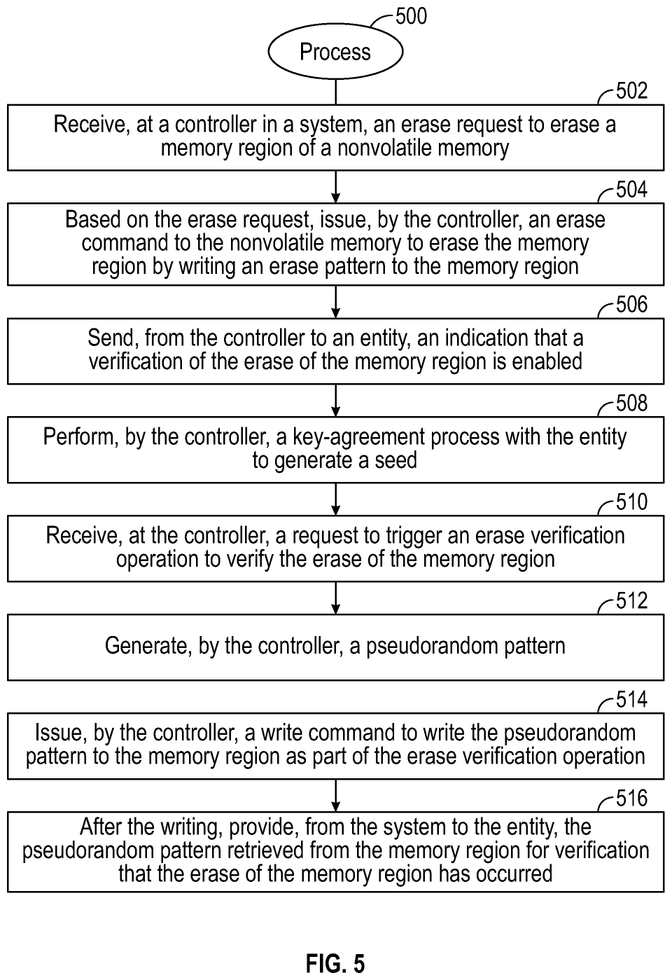

FIG. 5 is a flow diagram of a process 500 according to some examples. The process includes receiving (at 502), at a controller in a system, an erase request to erase a memory region of a nonvolatile memory. The controller may be a BMC or a different type of controller.

Based on the erase request, the process 500 includes issuing (at 504), by the controller, an erase command to the nonvolatile memory to erase the memory region by writing an erase pattern to the memory region. The erase command may be issued to a security processor to erase the memory region in a secure memory (e.g., 118 in FIG. 1) or to an external memory (e.g., 120 in FIG. 1).

The process 500 includes sending (at 506), from the controller to an entity, an indication that a verification of the erase of the memory region is enabled. The controller may include a verification state that is set by the controller in response to an erase operation of the nonvolatile memory.

The process 500 includes performing (at 508), by the controller, a key-agreement process with an entity to generate a seed. For example, the key-agreement process may be according to a key-agreement algorithm where the controller and the entity contribute to generating the seed without exchanging the seed with each other (so that the seed is not exposed to potential unauthorized access).

The process 500 includes receiving (at 510), at the controller, a request to trigger an erase verification operation to verify the erase of the memory region. The request may be the erase verification request 142 of FIG. 1, for example.

The process 500 includes generating (at 512), by the controller, a pseudorandom pattern based on the seed. The pseudorandom pattern may include a random sequence of bits generated by a DRBG, such as 152 in FIG. 1.

The process 500 includes issuing (at 512), by the controller responsive to the request, a write command to write the pseudorandom pattern to the memory region as part of the erase verification operation. After the writing, the process 500 includes providing (at 514), from the system to the entity, the pseudorandom pattern retrieved from the memory region for verification that the erase of the memory region has occurred. The entity compares the retrieved pseudorandom pattern to a stored pattern to perform the verification.

A “BMC” can refer to a specialized service controller that monitors the physical state of a computer system using sensors and communicates with a remote management system (that is remote from the computer system) through an independent “out-of-band” connection. The BMC can perform management tasks to manage components of the computer system. Examples of management tasks that can be performed by the BMC can include any or some combination of the following: power control to perform power management of the computer system (such as to transition the computer system between different power consumption states in response to detected events), thermal monitoring and control of the computer system (such as to monitor temperatures of the computer system and to control thermal management states of the computer system), fan control of fans in the computer system, system health monitoring based on monitoring measurement data from various sensors of the computer system, remote access of the computer system (to access the computer system over a network, for example), remote reboot of the computer system (to trigger the computer system to reboot using a remote command), system setup and deployment of the computer system, system security to implement security procedures in the computer system, and so forth.

In some examples, the BMC can provide so-called “lights-out” functionality for a computer system. The lights out functionality may allow a user, such as a systems administrator, to perform management operations on the computer system even if an OS is not installed or not functional on the computer system.

Moreover, in some examples, the BMC can run on auxiliary power provided by an auxiliary power supply (e.g., a battery); as a result, the computer system does not have to be powered on to allow the BMC to perform the BMC's operations. The auxiliary power supply is separate from a main power supply that supplies powers to other components (e.g., a main processor, a memory, an input/output (I/O) device, etc.) of the computer system.

In some examples, in addition to the BMC in each computer system, an additional management controller (separate from the BMCs) can be used to interact with the BMCs to perform management of the computer system. In examples where the computer systems are server computers (or other types of computer systems) mounted in a rack, the additional management controller can be referred to as a rack management controller (RMC). A “rack” refers to a mounting structure that has supports for multiple computer systems.

A storage medium (e.g., 400 in FIG. 4) can include any or some combination of the following: a semiconductor memory device such as a DRAM or SRAM, an EPROM, an EEPROM, and a flash memory; a magnetic disk such as a fixed, floppy and removable disk; another magnetic medium including tape; an optical medium such as a compact disk (CD) or a digital video disk (DVD); or another type of storage device. Note that the instructions discussed above can be provided on one computer-readable or machine-readable storage medium, or alternatively, can be provided on multiple computer-readable or machine-readable storage media distributed in a large system having possibly plural nodes. Such computer-readable or machine-readable storage medium or media is (are) considered to be part of an article (or article of manufacture). An article or article of manufacture can refer to any manufactured single component or multiple components. The storage medium or media can be located either in the machine running the machine-readable instructions, or located at a remote site from which machine-readable instructions can be downloaded over a network for execution.

In the present disclosure, use of the term “a,” “an,” or “the” is intended to include the plural forms as well, unless the context clearly indicates otherwise. Also, the term “includes,” “including,” “comprises,” “comprising,” “have,” or “having” when used in this disclosure specifies the presence of the stated elements, but do not preclude the presence or addition of other elements.

In the foregoing description, numerous details are set forth to provide an understanding of the subject disclosed herein. However, implementations may be practiced without some of these details. Other implementations may include modifications and variations from the details discussed above. It is intended that the appended claims cover such modifications and variations.

What is claimed is:

1. A system comprising:
a nonvolatile memory to store information; and
a controller subsystem to:
receive an input to trigger an erase verification operation after an erase of a memory region of the nonvolatile memory containing the information,
generate a pseudorandom pattern in response to the input,
write the pseudorandom pattern to the memory region as part of the erase verification operation, and
after the writing, provide, from the nonvolatile memory to an entity, the pseudorandom pattern retrieved from the memory region for verification by the entity that the erasing of the information of the memory region has occurred.

2. The system of claim 1, wherein the controller subsystem comprises:
a first controller to receive the input to trigger the erase verification operation, generate the pseudorandom pattern, and write the pseudorandom pattern to the memory region; and
a second controller to read the pseudorandom pattern from the nonvolatile memory and provide the pseudorandom pattern read from the memory region to the entity, wherein the second controller is different from the first controller.

3. The system of claim 2, wherein the first controller is a baseboard management controller.

4. The system of claim 1, wherein the controller subsystem comprises a controller to receive the input to trigger the erase verification operation, generate the pseudorandom pattern, and write the pseudorandom pattern to the memory region, the controller to further:
receive a trigger to restart the controller that causes a removal of power from the controller;
after the restart of the controller, receive, from the entity, a read request to retrieve the pseudorandom pattern from the memory region; and
provide, from the controller to the entity, the pseudorandom pattern retrieved from the memory region for the verification after the restart of the controller.

5. The system of claim 1, wherein the controller subsystem is to:
receive a read request to read the pseudorandom pattern from the nonvolatile memory,
wherein the pseudorandom pattern is retrieved from the memory region based on the read request.

6. The system of claim 5, wherein the read request is for one or more arbitrary subregions of the memory regions, and wherein the pseudorandom pattern provided to the entity is retrieved from the one or more arbitrary subregions.

7. The system of claim 1, wherein the controller subsystem is to generate a seed based on a key-generation process with the entity.

8. The system of claim 7, wherein the pseudorandom pattern is a deterministic random sequence of bits generated based on the seed.

9. The system of claim 1, wherein the pseudorandom pattern written to the memory region as part of the erase verification operation is different from an erase pattern written to the memory region to erase the information in the memory region.

10. The system of claim 9, wherein the controller subsystem is to erase the information in the memory region by writing the erase pattern to the memory region.

11. The system of claim 1, wherein the controller subsystem is to:
after the erase of the memory region of the nonvolatile memory containing the information, enable remote verification of the erase, and
send, to the entity, an indication that remote verification of the erase is enabled.

12. The system of claim 11, wherein the input to trigger the erase verification operation is provided by the entity in response to the indication received by the entity from the controller subsystem.

13. A non-transitory machine-readable storage medium comprising instructions that upon execution cause a computer to:
receive, from a controller in a system, an indication that remote verification of an erase of a memory region in a nonvolatile memory of the system is enabled;
send, from the computer to the system after the receipt of the indication, an input to trigger an erase verification operation to verify the erase of the memory region;
receive, at the computer from the system, a pseudorandom pattern written by the controller to the memory region as part of the erase verification operation, wherein the pseudorandom pattern is generated by the controller based on a seed; and
compare the received pseudorandom pattern with a stored pattern to verify that the erase of the memory region has occurred.

14. The non-transitory machine-readable storage medium of claim 13, wherein the instructions upon execution cause the computer to:
generate the seed based on a key-agreement process between the computer and the controller.

15. The non-transitory machine-readable storage medium of claim 14, wherein the instructions upon execution cause the computer to:
generate the stored pattern using the seed; and
store the stored pattern in a memory of the computer.

16. The non-transitory machine-readable storage medium of claim 13, wherein the instructions upon execution cause the computer to:
send, to the system, a read request for one or more arbitrary subregions of the memory region,
wherein the pseudorandom pattern received at the computer from the system is retrieved from the one or more arbitrary subregions of the memory region.

17. The non-transitory machine-readable storage medium of claim 13, wherein the controller comprises a first controller, and the pseudorandom pattern received at the computer from the system is retrieved by a second controller different from the first controller.

18. The non-transitory machine-readable storage medium of claim 13, wherein the pseudorandom pattern received at the computer from the system is retrieved by the controller after a restart of the controller.

19. A method comprising:
receiving, at a controller in a system, an erase request to erase a memory region of a nonvolatile memory;
based on the erase request, issuing, by the controller, an erase command to the nonvolatile memory to erase the memory region by writing an erase pattern to the memory region;
sending, from the controller to an entity, an indication that a verification of the erase of the memory region is enabled;
performing, by the controller, a key-agreement process with the entity to generate a seed;
receiving, at the controller, a request to trigger an erase verification operation to verify the erase of the memory region;
generating, by the controller responsive to the request, a pseudorandom pattern based on the seed,
issuing, by the controller, a write command to write the pseudorandom pattern to the memory region as part of the erase verification operation; and
after the writing, providing, from the system to the entity, the pseudorandom pattern retrieved from the memory region for verification that the erase of the memory region has occurred.

20. The method of claim 19, wherein the pseudorandom pattern is generated by a deterministic random bit generator of the controller based on the seed.
